(19) United States
(12) Patent Application Publication
(10) Pub. No.: US 2024/0312524 A1
(43) Pub. Date: Sep. 19, 2024

(54) SEMICONDUCTOR MEMORY DEVICE FOR PERFORMING PROGRAM OPERATION

(71) Applicant: SK hynix Inc., Gyeonggi-do (KR)

(72) Inventors: Hyung Jin CHOI, Gyeonggi-do (KR); In Gon YANG, Gyeonggi-do (KR)

(21) Appl. No.: 18/451,104

(22) Filed: Aug. 17, 2023

(30) Foreign Application Priority Data
Mar. 15, 2023 (KR) 10-2023-0033794

(51) Int. Cl. G11C 16/10; G11C 16/04; G11C 16/08; G11C 16/24

(52) U.S. Cl. CPC G11C 16/102; G11C 16/0433; G11C 16/08; G11C 16/24

(57) ABSTRACT

Provided herein may be a semiconductor memory device. The semiconductor memory device may include first and second cell strings. The first cell string is coupled to a first bit line and includes a first drain select transistor, a plurality of memory cells, and a first source select transistor. The second cell string is coupled to the first bit line and includes a second drain select transistor, a plurality of memory cells, and a second source select transistor. A plurality of data bits may be stored in a memory cell group formed by a first memory cell coupled to a first word line among memory cells included in the first cell string, and a second memory cell coupled to the first word line among memory cells included in the second cell string. The number of data bits stored in each of first and second memory cells may be a non-integer.

### CROSS-REFERENCE TO RELATED APPLICATION

The present application claims priority under 35 U.S.C. § 119(a) to Korean patent application number 10-2023-0033794 filed on Mar. 15, 2023, the entire disclosure of which is incorporated by reference herein.

### BACKGROUND

### 1. Field of Invention

Various embodiments of the present disclosure relate to an electronic device, and more particularly to a semiconductor memory device for performing a program operation.

### 2. Description of Related Art

A semiconductor memory device may be formed in a two-dimensional (2D) structure in which strings are horizontally arranged on a semiconductor substrate. Alternatively, the semiconductor memory device may be formed in a three-dimensional (3D) structure in which strings are vertically stacked on a semiconductor substrate. As a 2D memory device is reaching its physical scaling limit (i.e., limit in the degree of integration), a 3D memory device including a plurality of memory cells vertically stacked on a semiconductor substrate has been produced.

A single-level cell (SLC) may store 1 bit per memory cell. In this case, the threshold voltage of a single-level cell may belong to one of two states. In order to increase the size of data stored in a memory device, each of a plurality of memory cells may store data of more than one bit. In this case, the threshold voltage of each memory cell may belong to one of more than two states.

### SUMMARY

Various embodiments of the present disclosure are directed to a semiconductor memory device that is capable of storing maximum data while maintaining the reliability of memory cells.

An embodiment of the present disclosure may provide for a semiconductor memory device. The semiconductor memory device may include a first cell string and a second cell string. The first cell string may be coupled to a first bit line. The first cell string may include a first drain select transistor, a plurality of memory cells, and a first source select transistor. The second cell string may be coupled to the first bit line. The second cell string may include a second drain select transistor, a plurality of memory cells, and a second source select transistor. The semiconductor memory device may store a plurality of data bits in a memory cell group formed by a first memory cell coupled to a first word line among the plurality of memory cells included in the first cell string, and a second memory cell coupled to the first word line among the plurality of memory cells included in the second cell string. The number of data bits stored in each of the first and second memory cells may be a non-integer.

An embodiment of the present disclosure may provide for a semiconductor memory device. The semiconductor memory device may include first to fourth cell strings. The first cell string may be coupled to a first bit line. The first cell string may include a first drain select transistor, a plurality of memory cells, and a first source select transistor. The second cell string may be coupled to the first bit line. The second cell string may include a second drain select transistor, a plurality of memory cells, and a second source select transistor. The third cell string may be coupled to the first bit line. The third cell string may include a third drain select transistor, a plurality of memory cells, and a third source select transistor. The fourth cell string may be coupled to the first bit line. The fourth cell string may include a fourth drain select transistor, a plurality of memory cells, and a fourth source select transistor. The semiconductor memory device may store a plurality of data bits in a first memory cell group formed by a first memory cell coupled to a first word line among the plurality of memory cells included in the first cell string, and a third memory cell coupled to the first word line among the plurality of memory cells included in the third cell string. A number of data bits stored in each of the first and third memory cells may be a non-integer.

An embodiment of the present disclosure may provide for a semiconductor memory device. The semiconductor memory device may include first to third cell strings. The first cell string may be coupled to a first bit line. The first cell string may include a first drain select transistor, a plurality of memory cells, and a first source select transistor. The second cell string may be coupled to the first bit line. The second cell string may include a second drain select transistor, a plurality of memory cells, and a second source select transistor. The third cell string may be coupled to the first bit line. The third cell string may include a third drain select transistor, a plurality of memory cells, and a third source select transistor. The semiconductor memory device may store a plurality of data bits in a memory cell group formed by a first memory cell coupled to a first word line among the plurality of memory cells included in the first cell string, a second memory cell coupled to the first word line among the plurality of memory cells included in the second cell string, and a third memory cell coupled to the first word line among the plurality of memory cells included in the third cell string.

An embodiment of the present disclosure may provide for a semiconductor memory device. The semiconductor memory device may include a plurality of cell strings coupled between a bit line and a source line. Each of the plurality of cell strings may include a drain select transistor coupled to the bit line, a source select transistor coupled to the source line, and a plurality of memory cells coupled in series between the drain select transistor and the source select transistor. The plurality of memory cells may be coupled to respectively word lines. The semiconductor memory device may store a plurality of data bits in a memory cell group formed by at least a part of the memory cells of the cell strings, the part being coupled to a first word line among the word lines.

An embodiment of the present disclosure may provide for a memory device. The memory device may include a memory cell array including a group configured by a N number of memory cells and a control circuit configured to control the array to store therein a X number of bits into the group. X is a greatest integer satisfying a condition [X< and 2X<], DK representing a number of bits that a Kth one of the memory cell is capable of storing therein, and MK representing a number of possible states of the Kth memory cell, MK being less than a number of states that the Kth memory cell is capable of having, the memory cells within the group are disposed in a row and respective columns within the array, and the respective columns are coupled to a bit line and respective drain select lines.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory block BLKa of memory blocks BLK1 to BLKz of FIG. 1.

FIG. 3 is a diagram for describing an example of string-groups forming a memory block according to an embodiment of the present disclosure.

FIG. 4 is a circuit diagram illustrating in detail a first string-group among the string-groups illustrated in FIG. 3.

FIG. 5 is a circuit diagram illustrating some of cell strings included in first and second string-groups according to an embodiment of the present disclosure.

FIG. 6 is a diagram for describing an example of string-groups forming a memory block according to an embodiment of the present disclosure.

FIG. 7 is a circuit diagram illustrating an example of some of cell strings included in first to fourth string-groups according to an embodiment of the present disclosure.

FIG. 8 is a graph illustrating threshold voltage distributions of memory cells in which a memory cell group stores therein three bits and the memory cell group includes two memory cells according to an embodiment of the present disclosure.

FIG. 9 is a table illustrating examples of data bits corresponding to a combination of threshold voltage states of two memory cells according to an embodiment of the present disclosure.

FIG. 10 is a graph illustrating threshold voltage distributions of memory cells in which a memory cell group stores therein five bits and the memory cell group includes two memory cells.

FIG. 11 is a diagram for describing a combination of memory cells included in a memory cell group according to an embodiment of the present disclosure.

FIG. 12 is a diagram for describing a combination of memory cells included in a memory cell group according to an embodiment of the present disclosure.

FIG. 13A is a graph illustrating threshold voltage states of a memory cell MC11 of FIG. 12.

FIG. 13B is a graph illustrating threshold voltage states of a memory cell MC51 of FIG. 12.

FIG. 14 is a diagram for describing a combination of memory cells included in a memory cell group according to an embodiment of the present disclosure.

FIG. 15A is a graph illustrating threshold voltage states of a memory cell MC11 of FIG. 14.

FIG. 15B is a graph illustrating threshold voltage states of memory cells MC21 and MC31 of FIG. 14.

### DETAILED DESCRIPTION

Specific structural or functional descriptions in the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in the specification.

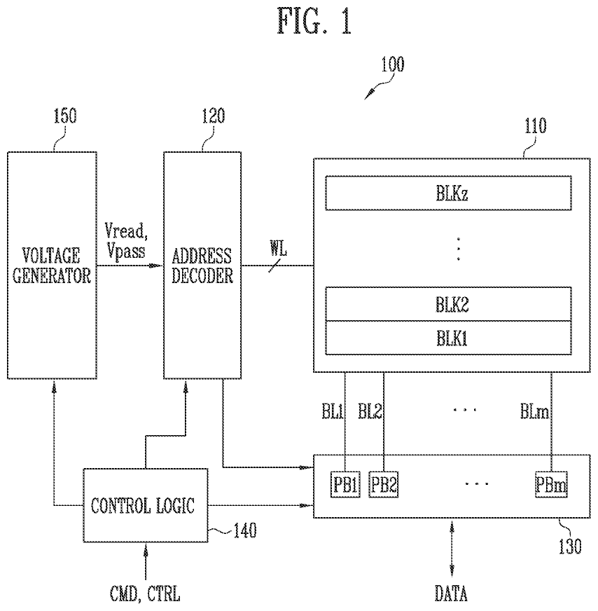

FIG. 1 is a block diagram illustrating a semiconductor memory device 100 according to an embodiment of the present disclosure.

Referring to FIG. 1, the semiconductor memory device 100 may include a memory cell array 110, an address decoder 120, a read and write circuit 130, a control logic 140, and a voltage generator 150.

The memory cell array 110 may include a plurality of memory blocks BLK1 to BLKz. The memory blocks BLK1 to BLKz are coupled to the address decoder 120 through word lines WL. The memory blocks BLK1 to BLKz are coupled to the read and write circuit 130 through bit lines BL1 to BLm. Each of the memory blocks BLK1 to BLKz includes a plurality of memory cells. In an embodiment, the plurality of memory cells may be nonvolatile memory cells, and may be implemented as nonvolatile memory cells having a vertical channel structure. The memory cell array 110 may be implemented as a memory cell array having a two-dimensional (2D) structure. In an embodiment, the memory cell array 110 may be implemented as a memory cell array having a three-dimensional (3D) structure. Moreover, each of the memory cells included in the memory cell array may store at least one bit of data. In an embodiment, each of the memory cells included in the memory cell array 110 may be a single-level cell (SLC) capable of storing one bit of data. In an embodiment, each of the memory cells included in the memory cell array 110 may be a multi-level cell (MLC) capable of storing two bits of data. In an embodiment, each of the memory cells included in the memory cell array 110 may be a triple-level cell (TLC) capable of storing three bits of data. In an embodiment, each of the memory cells included in the memory cell array 110 may be a quad-level cell (QLC) capable of storing four bits of data. In accordance with an embodiment, the memory cell array 110 may include a plurality of memory cells, each of which is capable of storing five or more bits of data.

The address decoder 120 is coupled to the memory cell array 110 through the word lines WL. The address decoder 120 may be operated under the control of the control logic 140. The address decoder 120 receives addresses through an input/output buffer (not illustrated) provided in the semiconductor memory device 100.

The address decoder 120 may decode the block address among the received addresses. The address decoder 120 selects at least one memory block according to the decoded block address. When a read voltage apply operation is performed during a read operation, the address decoder 120 may apply a read voltage Vread, generated by the voltage generator 150, to a selected word line of a selected memory block, and may apply a pass voltage Vpass to the remaining word lines, that is, unselected word lines. Further, during a program verify operation, the address decoder 120 may apply a verify voltage, generated by the voltage generator 150, to the selected word line of the selected memory block, and may apply the pass voltage Vpass to the unselected word lines.

The address decoder 120 may decode the column address among the received addresses. The address decoder 120 may transmit the decoded column address to the read and write circuit 130.

Each of the read and program operations of the semiconductor memory device 100 may be performed on a page basis. Addresses received in response to requests for the read and program operations may include a block address, a row address, and a column address. The address decoder 120 may select one memory block and one word line according to the block address and the row address. The column address may be decoded by the address decoder 120, and may then be provided to the read and write circuit 130.

The address decoder 120 may include a block decoder, a row decoder, a column decoder, an address buffer, etc.

The read and write circuit 130 includes a plurality of page buffers PB1 to PBm. The read and write circuit 130 may be operated as a “read” circuit during a read operation on the memory cell array 110 and as a “write” circuit during a write operation. The plurality of page buffers PB1 to PBm may be coupled to the memory cell array 110 through the bit lines BL1 to BLm. In order to sense threshold voltages of the memory cells during a read operation and a program verify operation, each of the page buffers PB1 to PBm may sense, through a sensing node, a change in the amount of flowing current depending on the program state of a corresponding memory cell and latch the sensed change as sensing data while continuously supplying a sensing current to the bit lines coupled to the memory cells. The read and write circuit 130 may be operated in response to page buffer control signals output from the control logic 140.

During a read operation, the read and write circuit 130 may sense data stored in the memory cells and temporarily store read data, and may then output data DATA to the input/output buffer (not illustrated) of the semiconductor memory device 100. In an example embodiment, the read and write circuit 130 may include a column select circuit or the like as well as the page buffers (or page registers).

The control logic 140 is coupled to the address decoder 120, the read and write circuit 130, and the voltage generator 150. The control logic 140 may receive a command CMD and a control signal CTRL through the input/output buffer (not illustrated) of the semiconductor memory device 100. The control logic 140 may control the overall operation of the semiconductor memory device 100 in response to the control signal CTRL. Furthermore, the control logic 140 may output a control signal for controlling a precharge potential level at the sensing node of the plurality of page buffers PB1 to PBm. The control logic 140 may control the read and write circuit 130 to perform a read operation on the memory cell array 110.

The voltage generator 150 may generate the read voltage Vread and the pass voltage Vpass required for a read operation in response to the control signal output from the control logic 140. The voltage generator 150 may include a plurality of pumping capacitors for receiving the internal supply voltage so as to generate a plurality of voltages having various voltage levels, and may generate a plurality of voltages by selectively enabling the plurality of pumping capacitors under the control of the control logic 140.

The address decoder 120, the read and write circuit 130, and the voltage generator 150 may function as a “peripheral circuit” which performs a read operation, a write operation, and an erase operation on the memory cell array 110. The peripheral circuits may perform the read operation, the write operation, and the erase operation on the memory cell array 110 under the control of the control logic 140.

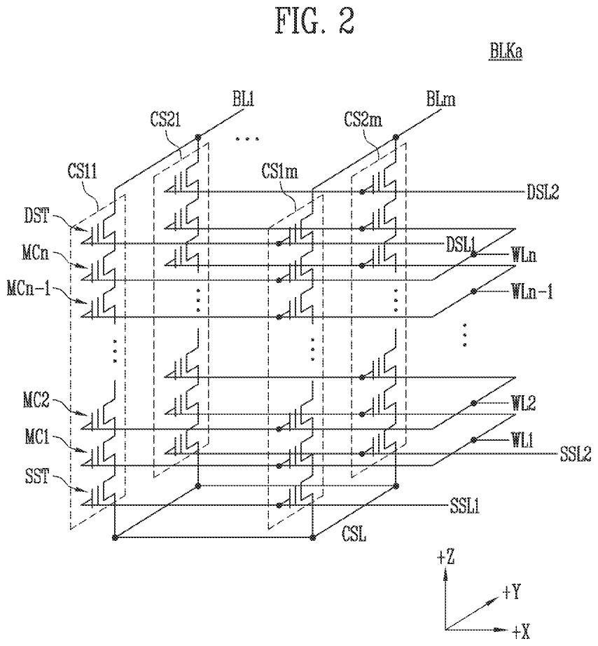

FIG. 2 is a circuit diagram illustrating a memory block BLKa of memory blocks BLK1 to BLKz of FIG. 1.

Referring to FIG. 2, the memory block BLKa may include a plurality of cell strings CS11 to CS1m and CS21 to CS2m. In the memory block BLKa, m cell strings may be arranged in a row direction (i.e., a positive (+) X direction). In FIG. 2, two cell strings are illustrated as being arranged in a column direction (i.e., a positive (+) Y direction). However, this illustration is made for convenience of description, and it will be understood that three or more cell strings may be arranged in the column direction.

Each of the plurality of cell strings CS11 to CS1m and CS21 to CS2m includes at least one source select transistor SST, first to n-th memory cells MC1 to MCn, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST in each cell string is coupled between a common source line CSL and the memory cells MC1 to MCn.

In an embodiment, the source select transistors of cell strings arranged in the same row are coupled to a source select line extending in a row direction, and the source select transistors of cell strings arranged in different rows are coupled to different source select lines. In FIG. 2, the source select transistors of the cell strings CS11 to CS1m in a first row are coupled to a first source select line SSL1. The source select transistors of the cell strings CS21 to CS2m in a second row are coupled to a second source select line SSL2.

In an embodiment, the source select transistors of the cell strings CS11 to CS1m and CS21 to CS2m may be coupled in common to one source select line.

The first to n-th memory cells MC1 to MCn in each cell string are coupled in series between the source select transistor SST and the drain select transistor DST. Gates of the first to n-th memory cells MC1 to MCn are respectively coupled to first to n-th word lines WL1 to WLn.

The drain select transistor DST of each cell string is coupled between the corresponding bit line and the memory cells MC1 to MCn. The drain select transistors DST of cell strings arranged in the row direction are coupled to a drain select line extending in the row direction. The drain select transistors of the cell strings CS11 to CS1m in the first row are coupled to a first drain select line DSL1. The drain select transistors of the cell strings CS21 to CS2m in the second row are coupled to a second drain select line DSL2.

Cell strings arranged in the column direction may be coupled to bit lines extending in the column direction. In FIG. 2, the cell strings CS11 and CS21 in a first column are coupled to a first bit line BL1. The cell strings CS1m and CS2m in an m-th column are coupled to an m-th bit line BLm.

Memory cells coupled to the same word line in cell strings arranged in the row direction form one page. For example, memory cells coupled to the first word line WL1 among the cell strings CS11 to CS1m in the first row form one page. Memory cells coupled to the first word line WL1 among the cell strings CS21 to CS2m in the second row form one additional page. Cell strings arranged in the direction of one row may be selected by selecting one of the drain select lines DSL1 and DSL2. One page may be selected from the selected cell strings by selecting one of the word lines WL1 to WLn.

In an embodiment, instead of the first to m-th bit lines BL1 to BLm, even bit lines and odd bit lines may be provided. Even-numbered cell strings, among the cell strings CS11 to CS1m or CS21 to CS2m arranged in a row direction, may be coupled to respective even bit lines. Odd-numbered cell strings, among the cell strings CS11 to CS1m or CS21 to CS2m arranged in the row direction, may be coupled to respective odd bit lines.

In an embodiment, one or more of first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As the number of dummy memory cells that are provided is increased, the reliability of operation of the memory block BLKa may be improved, whereas the size of the memory block BLKa may be increased. As the number of dummy memory cells that are provided is decreased, the size of the memory block BLKa may be decreased, whereas the reliability of operation of the memory block BLKa may be deteriorated.

In order to efficiently control the one or more dummy memory cells, respective dummy memory cells may have required threshold voltages. Before or after an erase operation on the memory block BLKa is performed, program operations may be performed on all or some of the dummy memory cells. When the erase operation is performed after the program operations have been performed, the respective dummy memory cells may have required threshold voltages by controlling voltages to be applied to dummy word lines coupled to respective dummy memory cells.

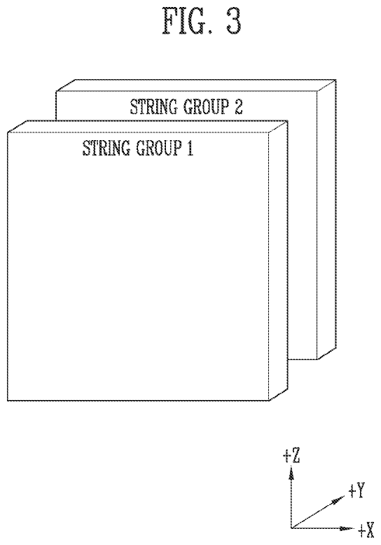

FIG. 3 is a diagram for describing an example of string-groups forming a memory block according to an embodiment of the present disclosure.

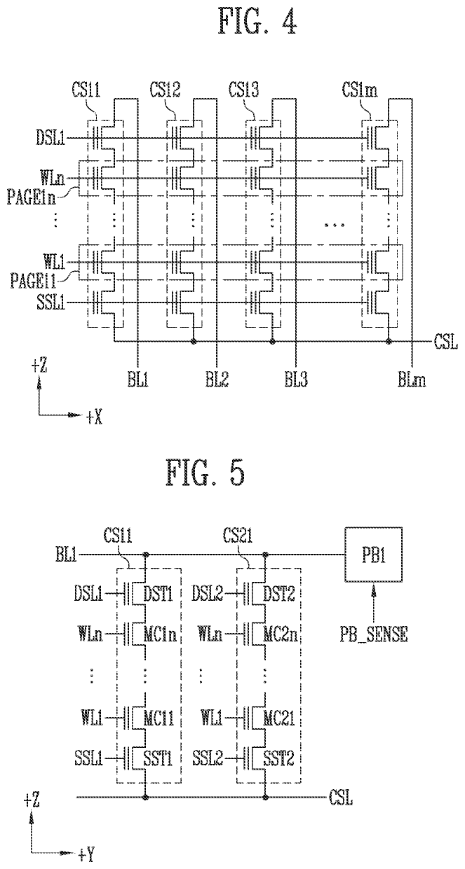

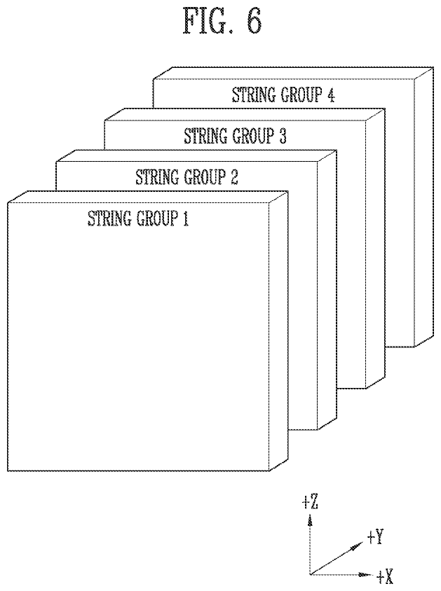

Referring to FIG. 3, string-groups STRING GROUP 1 and STRING GROUP 2 included in the memory block BLKa shown in FIG. 2 are illustrated. In an example, referring to FIG. 3 together with FIG. 2, the string-groups included in the memory block BLKa may be defined as cell strings which share a drain select line or a source select line. For example, in FIG. 2, cell strings CS11 to CS1m which share the first drain select line DSL1 and the first source select line SSL1 may form the first string-group STRING GROUP 1. Furthermore, the cell strings CS21 to CS2m which share the second drain select line DSL2 and the second source select line SSL2 may form the second string-group STRING GROUP 2. The memory block may include two string-groups STRING GROUP 1 and STRING GROUP 2 arranged in a +Y direction. Each of the string-groups STRING GROUP 1 and STRING GROUP 2 may include cell strings arranged in a row direction (i.e., +X direction). Each of the string-groups STRING GROUP 1 and STRING GROUP 2 may include pages arranged in a string direction (i.e., +Z direction). The detailed configuration of each string-group will be described below with reference to FIGS. 4 and 5.

FIG. 4 is a circuit diagram illustrating in detail a first string-group among the string-groups illustrated in FIG. 3. Since a second string-group may be configured in the same manner as the first string-group, a detailed circuit diagram of the second string-group is omitted here.

Referring to FIG. 4, the first string-group STRING GROUP 1 may include cell strings CS11 to CS1m which share a first drain select line DSL1 and a first source select line SSL1. The cell strings CS11 to CS1m included in the first string-group STRING GROUP 1 may be coupled in common to the first drain select line DSL1 and the first source select line SSL1. The cell strings CS11 to CS1m may be arranged in a +X direction in the first string-group STRING GROUP 1. The cell strings CS11 to CS1m may be coupled to corresponding bit lines BL1 to BLm, respectively.

The first string-group STRING GROUP 1 may include pages PAGE11 to PAGE1n arranged in a +Z direction. Each of the pages PAGE11 to PAGE1n may be a set of memory cells coupled to a corresponding one of word lines WL1 to WLn.

Although not illustrated in FIG. 4, the second string-group STRING GROUP 2 may also include cell strings CS21 to CS2m arranged in the +X direction. The second string-group STRING GROUP 2 may include pages PAGE21 to PAGE2n arranged in the +Z direction.

FIG. 5 is a circuit diagram illustrating some of cell strings included in first and second string-groups according to an embodiment of the present disclosure.

Referring to FIG. 5, a cell string CS11 included in the first string-group STRING GROUP 1 and a cell string CS21 included in the second string-group STRING GROUP 2 are illustrated. FIG. 5 may be a circuit diagram illustrating the memory block of FIG. 2 in a +X direction. Therefore, in FIG. 5, cell strings CS12 to CS1m included in the first string-group STRING GROUP 1 and cell strings CS22 to CS2m included in the second string-group STRING GROUP 2 are not illustrated.

The cell string CS11 in the first string-group STRING GROUP 1 includes memory cells MC11 to MC1n coupled between a first drain select transistor DST1 and a first source select transistor SST1. The cell string CS21 in the second string-group STRING GROUP 2 includes memory cells MC21 to MC2n coupled between a second drain select transistor DST2 and a second source select transistor SST2.

The cell string CS11 included in the first string-group STRING GROUP 1 and the cell string CS21 included in the second string-group STRING GROUP 2 are coupled in common to a bit line BL1. Meanwhile, a page buffer PB1 is coupled in common to the bit line BL1. The cell string CS11 included in the first string-group STRING GROUP 1 and the cell string CS21 included in the second string-group STRING GROUP 2 may share the page buffer PB1. The page buffer PB1 may be operated based on a signal PB_SENSE. Although not illustrated in FIG. 5, the page buffer PB1 may be operated based on a plurality of control signals other than the signal PB_SENSE.

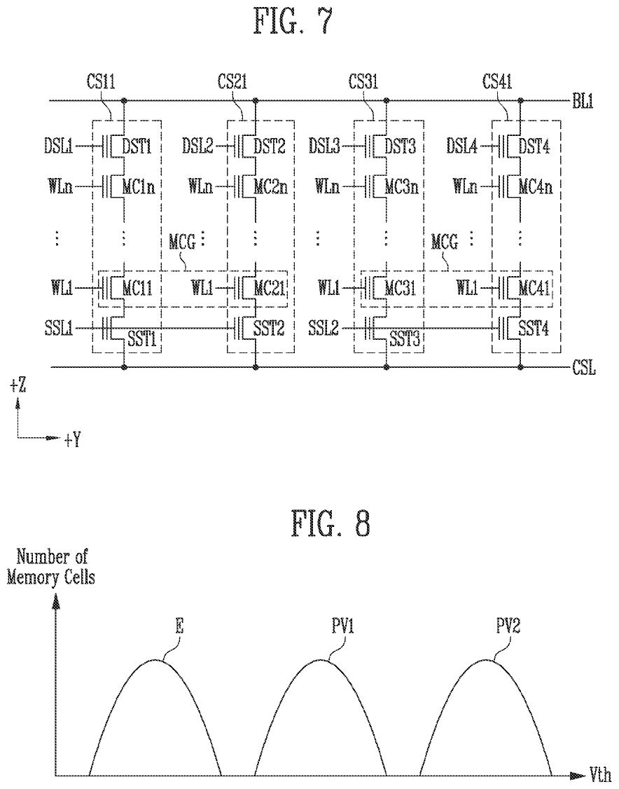

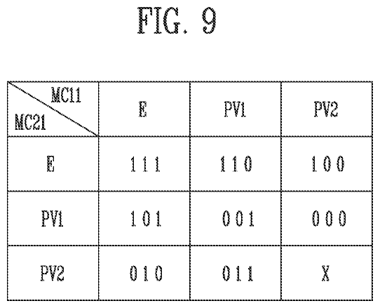

FIG. 6 is a diagram for describing an example of string-groups forming a memory block according to an embodiment of the present disclosure. FIG. 7 is a circuit diagram illustrating an example of some of cell strings included in first to fourth string-groups according to an embodiment of the present disclosure.

Referring to FIG. 6, the memory block may include four string-groups STRING GROUP 1 to STRING GROUP 4. As described above, each of the string-groups included in the memory block may be defined as cell strings which share a drain select line or a source select line.

Referring to FIG. 7, a cell string CS11 included in the first string-group STRING GROUP 1, a cell string CS21 included in the second string-group STRING GROUP 2, a cell string CS31 included in the third string-group STRING GROUP 3, and a cell string CS41 included in the fourth string-group STRING GROUP 4 are illustrated. FIG. 7 may be a circuit diagram illustrating the memory block of FIG. 6 in a +X direction.

The cell string CS11 in the first string-group STRING GROUP 1 includes memory cells MC11 to MC1n coupled between a first drain select transistor DST1 and a first source select transistor SST1. The cell string CS21 in the second string-group STRING GROUP 2 includes memory cells MC21 to MC2n coupled between a second drain select transistor DST2 and a second source select transistor SST2. The cell string CS31 in the third string-group STRING GROUP 3 includes memory cells MC31 to MC3n coupled between a third drain select transistor DST3 and a third source select transistor SST3. The cell string CS41 in the fourth string-group STRING GROUP 4 includes memory cells MC41 to MC4n coupled between a fourth drain select transistor DST4 and a fourth source select transistor SST4. As described above with reference to FIG. 5, the cell strings CS11, CS21, CS31, and CS41 included in the first to fourth string-groups STRING GROUP 1 to STRING GROUP 4 may be coupled in common to a bit line BL1. In this case, a page buffer may be coupled in common to the bit line BL1. That is, the cell strings CS11, CS21, CS31, and CS41 included in the first to fourth string-groups STRING GROUP 1 to STRING GROUP 4, respectively, may share a page buffer PB1.

Typically, an integer number of bits may be stored in one memory cell. On the other hand, in accordance with an embodiment of the present disclosure, at least two memory cells among memory cells coupled to the same word line may form one memory cell group. A combination of threshold voltage states of two or more memory cells configuring one memory cell group may correspond to an integer number of bits. In this case, the integer number of data bits may be stored in the memory cell group configured by the two or more memory cells, rather than being stored in each of the memory cells configuring the memory cell group. In this case, each of the memory cells configuring the memory cell group may be conceptually regarded as storing a non-integer number of bits.

For example, in FIG. 7, two adjacent memory cells MC11 and MC21 which share the source select line SSL1, among the memory cells MC11, MC21, MC31, and MC41 coupled to a first word line WL1, may form one memory cell group MCG. In particular, an integer number of data bits may be stored in the memory cell group MCG rather than being stored in each of the memory cells MC11 and MC21 included in the memory cell group MCG. For this operation, the integer number of data bits stored in the memory cell group MCG may be represented through a combination of the threshold voltage states of the memory cells MC11 and MC21 included in the memory cell group MCG.

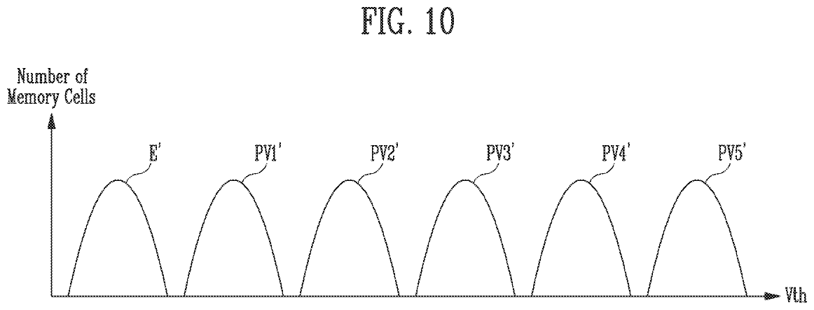

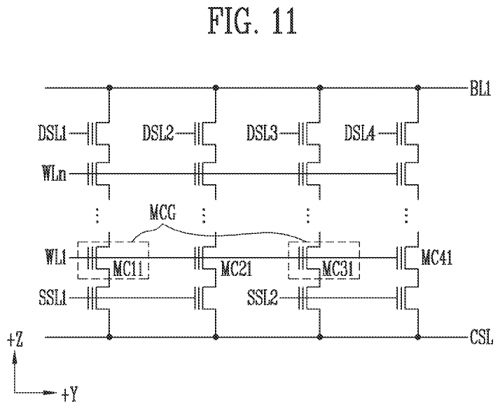

Similarly, two adjacent memory cells MC31 and MC41 which share the source select line SSL2, among the memory cells MC11, MC21, MC31, and MC41 coupled to the first word line WL1, may form a memory cell group MCG. Even in this case, an integer number of data bits stored in the memory cell group MCG may be represented through a combination of the threshold voltage states of the memory cells MC31 and MC41. Hereinafter, description will be made with reference to FIGS. 8 and 9.

FIG. 8 is a graph illustrating threshold voltage distributions of memory cells in which a memory cell group stores therein three bits and the memory cell group includes two memory cells according to an embodiment of the present disclosure.

Typically, the threshold voltage of each of memory cells may be one of 2^{N} states. For example, the number of threshold voltage states of a single-level cell (SLC) is 2, and the number of threshold voltage states of a multi-level cell (MLC) is 4. Further, the number of threshold voltage states of a triple-level cell (TLC) is 8, and the number of threshold voltage states of a quad-level cell (QLC) is 16.

As the number of threshold voltage distributions of the memory cells is larger, it is difficult to form threshold voltage distributions during a program operation, and a possibility of causing errors may be increased during a read operation. Therefore, when the number of threshold voltage states optimized for the characteristics of the memory cells is not 2N, data storage efficiency may be decreased.

According to an embodiment of the present disclosure, a plurality of memory cells may form a memory cell group, and an integer number of data bits are stored in the memory cell group. In this case, memory cells that are coupled to the same word line and are controlled through different drain select lines may be included in the memory cell group. That is, as illustrated in FIG. 7, the memory cells MC11 and MC21 that are coupled in common to the first word line WL1 and that are respectively controlled through the first and second drain select lines DSL1 and DSL2 may be included in one memory cell group MCG.

The number of threshold voltage states of memory cells included in the memory cell group does not necessarily have to be 2^{N}. Therefore, the number of threshold voltage states optimized for memory cell characteristics given in a process may be set.

For example, as illustrated in FIG. 8, each of the memory cells MC11, MC21, MC31, and MC41 of FIG. 7 may be programmed to have a threshold voltage corresponding to one of three threshold voltage states E, PV1, and PV2. In order to store two bits in each memory cell, each memory cell needs to be programmed to belong to one of four threshold voltage states, but, when it is difficult to form four threshold voltage states due to the characteristics of memory cells, each of the memory cells may be programmed to belong to one of three threshold voltage states, as illustrated in FIG. 8.

In this case, because each of the two memory cells can belong to one of three threshold voltage states, the total number of threshold voltage state cases that can be represented by combining two memory cells, each of which can belong to one of three threshold voltage states, is 9. Therefore, three data bits may be stored in the memory cell group including two memory cells, each of which can belong to one of three threshold voltage states. The particular number three (3) may be obtained from eight (8=2³), which is the largest power of 2 less than 9. Below, a description will be made in detail with reference to FIG. 9.

FIG. 9 is a table illustrating examples of data bits corresponding to a combination of the threshold voltage states of two memory cells according to an embodiment of the present disclosure. Referring to FIG. 9, three bits of data corresponding to the combination of respective threshold voltage states of memory cells MC11 and MC21 are illustrated.

In an example, data bits corresponding to the case where the threshold voltages of both the memory cells MC11 and MC21 belonging to the memory cell group MCG are in an erase state E are “1 1 1”. Therefore, by the program operation of the semiconductor memory device 100, the threshold voltages of both the memory cells MC11 and MC21 included in the memory cell group corresponding to “1 1 1” are in the erase state E.

Furthermore, data bits corresponding to the case where the threshold voltage of the memory cell MC21 is in the erase state E and the threshold voltage of the memory cell MC11 is in the first program state PV1 are “1 1 0.” Therefore, by the program operation of the semiconductor memory device 100, the threshold voltages of the memory cells MC11 and MC21 included in the memory cell group corresponding to “1 1 0” correspond to the first program state PV1 and the erase state E, respectively. In this way, eight cases corresponding to the combination of three data bits may be mapped to the combinations of the threshold voltage states of the memory cells MC11 and MC21. Meanwhile, a combination corresponding to the case where the threshold voltages of both the memory cells MC11 and MC21 are in the second program state PV2 may not be used.

However, the table illustrated in FIG. 9 is only an example, and data bits may be mapped to combinations of the threshold voltage states of the memory cells MC11 and MC21 using various different schemes.

Referring to FIGS. 8 and 9 together, the semiconductor memory device according to an embodiment of the present disclosure may store odd bits of data in the memory cell group MCG including two memory cells MC11 and MC21. Therefore, each of the memory cells MC11 and MC21 included in the memory cell group MCG may be conceptually regarded as storing data of a non-integer number of bits. In the example of FIGS. 8 and 9, the memory cell group MCG may store therein three (3) bits and therefore each of the memory cells MC11 and MC21 within the memory cell group MCG may be conceptually regarded as storing therein 1.5 number of bits, i.e., the non-integer number of bits.

Generally, each of the memory cells may store data of an integer number of bits. That is, a single-level cell (SLC) may store one bit, a multi-level cell (MLC) may store two bits, and a triple-level cell (TLC) may store three bits. When each memory cell stores an integer (N) number of bits, the corresponding memory cell is programmed to belong to one of a total of 2^{N} threshold voltage states. That is, the single-level cell (SLC) may be programmed to belong to one of two threshold voltage states, the multi-level cell (MLC) may be programmed to belong to one of four threshold voltage states, and the triple-level cell (TLC) may be programmed to belong to one of eight threshold voltage states. Namely, the number of threshold voltage states used in the memory cell which stores data of an integer (N) number of bits is fixed at 2^{N}.

According to an embodiment of the present disclosure, the number of bits stored in each of the memory cells configuring a memory cell group is conceptually regarded as a non-integer, and thus the number of threshold voltage states used in a program operation on each memory cell does not need to be 2^{N}. Accordingly, bit data may be more flexibly stored depending on the characteristics of the memory cells.

When the memory cells MC11 and MC21 coupled to the same word line WL1 configures the memory cell group MCG among the memory cells included in the plurality of cell strings coupled to the bit line BL1 and the memory cell group MCG stores therein an integer number of data bits, the number of data bits stored in each of the memory cells MC11 and MC21 included in the memory cell group MCG may be conceptually regarded as a non-integer. In particular, according to the embodiment illustrated in FIG. 8, the memory cells MC11 and MC21 included in the memory cell group MCG may be controlled through different drain select lines DSL1 and DSL2, and may be through by the same source select line SSL1.

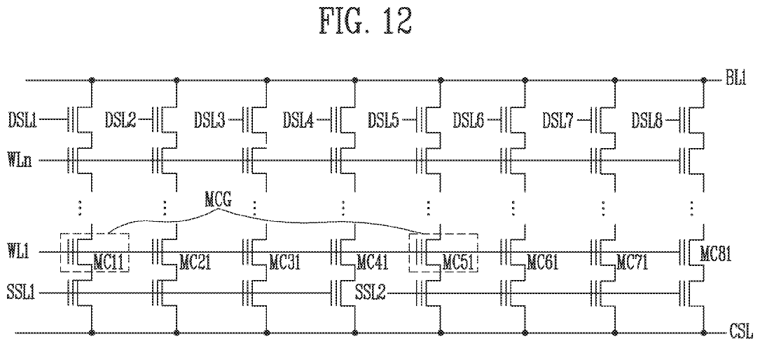

FIG. 10 is a graph illustrating threshold voltage distributions of memory cells in which a memory cell group stores therein five bits and the memory cell group includes two memory cells according to an embodiment of the present disclosure. FIGS. 8 and 9 illustrate the memory cell group MCG storing therein three bits. However, this is only an example, and the memory cell group MCG may store therein five bits.

Referring to FIG. 10, each of the memory cells MC11, MC21, MC31, and MC41 of FIG. 7 may be programmed to have a threshold voltage corresponding to one of six threshold voltage states E′, PV1′, PV2′, PV3′, PV4′, and PV5′. In the example of FIG. 10, because each of the two memory cells can belong to one of six threshold voltage states, the total number of threshold voltage state cases that can be represented by combining two memory cells, each of which can belong to one of six threshold voltage states, is 36. Therefore, five data bits may be stored in the memory cell group including two memory cells, each of which can belong to one of six threshold voltage states. The particular number five (5) may be obtained from 32 (=2⁵), which is the largest power of 2 less than 36.

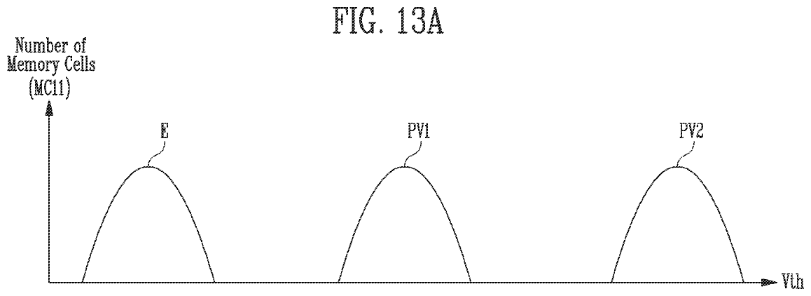

FIG. 11 is a diagram for describing a combination of memory cells included in a memory cell group according to an embodiment of the present disclosure. In the embodiment described above with reference to FIG. 7, two adjacent memory cells MC11 and MC21 among the memory cells MC11, MC21, MC31, and MC41 coupled to the first word line WL1 are illustrated as being included in the memory cell group MCG. However, this is only an example, and the plurality of memory cells included in the memory cell group MCG may be combined in various forms. For example, as illustrated in FIG. 11, memory cells MC11 and MC13 included in odd-numbered cell strings among the memory cells MC11, MC21, MC31, and MC41 coupled to the first word line WL1 may form one memory cell group MCG, and memory cells MC21 and MC41 included in even-numbered cell strings may form one memory cell group MCG.

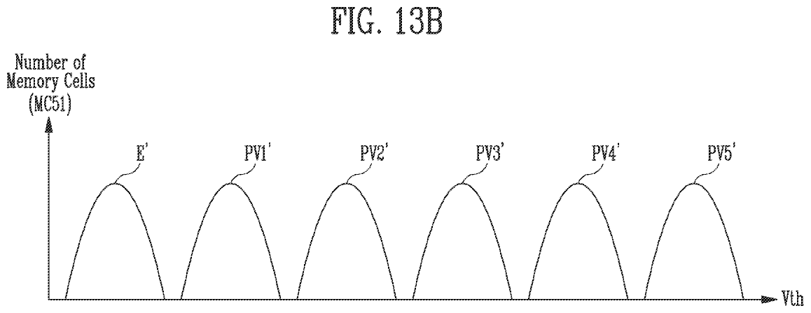

FIG. 12 is a diagram for describing a combination of memory cells included in a memory cell group according to an embodiment of the present disclosure. In the circuit diagrams of FIGS. 7 and 11, the structure of a memory block in which four cell strings are coupled to one bit line BL1 is illustrated. As shown in FIG. 12, eight cell strings may be coupled to one bit line BL1.

Referring to FIG. 12, an embodiment in which a memory cell MC11 disposed on a relatively outer portion and a memory cell MC51 disposed in a relatively central portion, among eight memory cells MC11 to MC81 coupled to a first word line WL1, are included in one memory cell group MCG is illustrated. Further, according to an embodiment of FIG. 12, memory cells MC21 and MC61 form one memory cell group MCG, memory cells MC31 and MC71 form one memory cell group MCG, and memory cells MC41 and MC81 form one memory cell group MCG.

For process reasons, the reliability of a memory cell disposed in a relatively outer portion may be low, and the reliability of a memory cell disposed in a relatively central portion may be high. As illustrated in FIG. 12, the memory cell disposed in the relatively outer portion and the memory cell disposed in the relatively central portion are configured as one memory cell group MCG, thus enabling the memory cell having relatively low reliability and the memory cell having relatively high reliability to be included in the memory cell group MCG.

In the embodiment of FIG. 12, the two memory cells MC11 and MC51 included in the memory cell group MCG may each be programmed to one of an identical number of threshold voltage states. In an example, the two memory cells MC11 and MC51 may each be programmed to one of three threshold voltage states illustrated in FIG. 8. In this case, the memory cell group MCG may store three data bits. In an example, the two memory cells MC11 and MC51 may each be programmed to one of six threshold voltage states illustrated in FIG. 10. In this case, the memory cell group MCG may store five data bits.

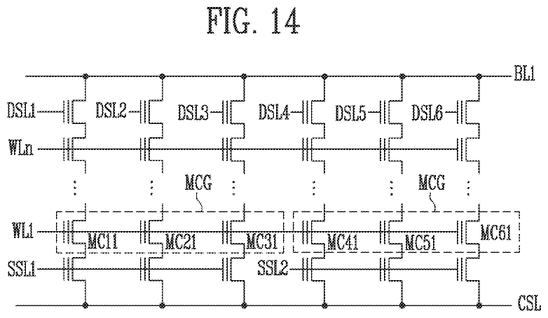

In an embodiment, the two memory cells MC11 and MC51 included in the memory cell group MCG may each be programmed to one of different numbers of threshold voltage states. By means of this, threshold voltage states may be assigned in conformity with different characteristics of respective memory cells included in the memory cell group MCG. Hereinafter, description will be made with reference to FIGS. 13A and 13B.

FIG. 13A is a graph illustrating threshold voltage states of the memory cell MC11 of FIG. 12. FIG. 13B is a graph illustrating the threshold voltage states of the memory cell MC51 of FIG. 12.

According to an embodiment of the present disclosure, the two memory cells MC11 and MC51 included in the memory cell group MCG may each be programmed to one of different numbers of threshold voltage states. For example, of the two memory cells MC11 and MC51 included in the memory cell group MCG, the memory cell MC11 disposed in a relatively outer portion may be programmed to one of three threshold voltage states E, PV1, and PV2, as illustrated in FIG. 13A. Furthermore, of the two memory cells MC11 and MC51 included in the memory cell group MCG, the memory cell MC51 disposed in a relatively central portion may be programmed to one of six threshold voltage states E′, PV1′, PV2′, PV3′, PV4′, and PV5′, as illustrated in FIG. 13B. In this case, because the two memory cells can belong to one of three threshold voltage states and one of six threshold voltage states, respectively, the total number of threshold voltage state cases that can be represented by combining the two memory cells, which can belong to one of three threshold voltage states and one of six threshold voltage states, is 18. Therefore, four data bits may be stored in the memory cell group including in two memory cells, which can belong to one of three threshold voltage states and one of six threshold voltage states. The particular number four (4) may be obtained from 16 (=2⁴), which is the largest power of 2 less than 18.

That is, of the memory cells MC11 and MC51 included in the memory cell group MCG, the memory cell MC11 having relatively low reliability is programmed to one of a smaller number of threshold voltage states E, PV1, and PV2, and the memory cell MC51 having relatively high reliability is programmed to one of a larger number of threshold voltage states E′, PV1′, PV2′, PV3′, PV4′, and PV5′, thus enabling as many data bits as possible to be stored in the memory cell group MCG while ensuring operational reliability.

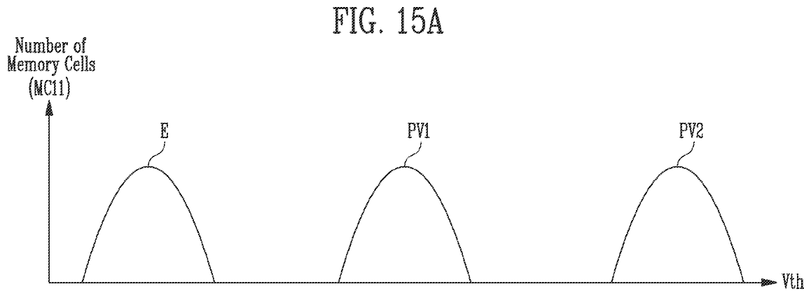

FIG. 14 is a diagram for describing an embodiment of a combination of memory cells included in a memory cell group according to an embodiment of the present disclosure.

By means of FIGS. 7, 11, and 12, the embodiments in which two memory cells form one memory cell group have been described. However, the present disclosure is not limited thereto, and three or more memory cells may form one memory cell group.

Referring to FIG. 14, the structure of a memory block in which six cell strings are coupled to one bit line BL1 is illustrated. In the embodiment illustrated in FIG. 14, among six memory cells MC11 to MC61 coupled to a first word line WL1, three adjacent memory cells MC11, MC21, and MC31 which share a source select line SSL1 may form one memory cell group MCG. Further, according to the embodiment illustrated in FIG. 14, among the six memory cells MC11 to MC61 coupled to the first word line WL1, three adjacent memory cells MC41, MC51, and MC61 which share a source select line SSL2 may form one memory cell group MCG.

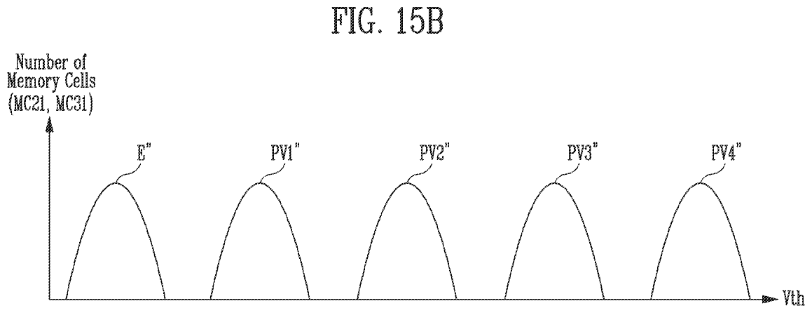

FIG. 15A is a graph illustrating threshold voltage states of the memory cell MC11 of FIG. 14. FIG. 15B is a graph illustrating threshold voltage states of the memory cells MC21 and MC31 of FIG. 14. Hereinafter, description will be made with reference to FIGS. 14, 15A, and 15B together.

Referring to FIG. 15A, among the memory cells MC11, MC21, and MC31 included in the memory cell group MCG, the memory cell MC11 disposed in a relatively outer portion may be programmed to one of three threshold voltage states E, PV1, and PV2, and each of the remaining two memory cells MC21 and MC31 may be programmed to one of five threshold voltage states E″, PV1″, PV2″, PV3″, and PV4″. In this case, because the three memory cells included in the memory cell group MCG can belong to one of three threshold voltage states, one of five threshold voltage states, and one of five threshold voltage states, respectively, the total number of threshold voltage state cases that can be represented by combining the three memory cells, which can belong to one of three threshold voltage states, one of five threshold voltage states, and one of five threshold voltage states, is 75. Therefore, six data bits may be stored in the memory cell group including three memory cells, which can belong to one of three threshold voltage states, one of five threshold voltage states, and one of five threshold voltage states. The particular number six (6) may be obtained from 64 (=2⁶), which is the largest power of 2 less than 75.

The present disclosure may provide a semiconductor memory device that is capable of storing maximum data while maintaining the reliability of memory cells.

Although embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of this disclosure is not limited by the embodiments and the accompanying drawings. The spirit and scope of the disclosure should be interpreted in connection with the appended claims and encompass all equivalents falling within the scope of the appended claims. Furthermore, the embodiments may be combined to form additional embodiments.

What is claimed is:

1. A semiconductor memory device comprising:
a first cell string coupled to a first bit line, the first cell string including a first drain select transistor, a plurality of memory cells, and a first source select transistor; and
a second cell string coupled to the first bit line, the second cell string including a second drain select transistor, a plurality of memory cells, and a second source select transistor,
wherein a plurality of data bits are stored in a memory cell group formed by a first memory cell coupled to a first word line among the plurality of memory cells included in the first cell string, and a second memory cell coupled to the first word line among the plurality of memory cells included in the second cell string, and
wherein a number of data bits stored in each of the first and second memory cells is a non-integer.

2. The semiconductor memory device according to claim 1, wherein:
the first cell string and the second cell string are disposed adjacent to each other, and
the first drain select transistor and the second drain select transistor are controlled through different drain select lines.

3. The semiconductor memory device according to claim 1, wherein the first source select transistor and the second source select transistor are controlled through an identical source select line.

4. The semiconductor memory device according to claim 1, wherein the first memory cell and the second memory cell are each programmed to one of an identical number of threshold voltage states.

5. The semiconductor memory device according to claim 4, wherein:
the first memory cell and the second memory cell are each programmed to one of three threshold voltage states, and
the memory cell group stores three bits of data.

6. The semiconductor memory device according to claim 4, wherein:
the first memory cell and the second memory cell are each programmed to one of three threshold voltage states, and
the memory cell group stores five bits of data.

7. The semiconductor memory device according to claim 1, wherein the first memory cell and the second memory cell are each programmed to one of different numbers of threshold voltage states.

8. The semiconductor memory device according to claim 7, wherein:
the first memory cell is programmed to one of three threshold voltage states,
the second memory cell is programmed to one of six threshold voltage states, and
the memory cell group stores four bits of data.

9. A semiconductor memory device comprising:
a first cell string coupled to a first bit line, the first cell string including a first drain select transistor, a plurality of memory cells, and a first source select transistor;
a second cell string coupled to the first bit line, the second cell string including a second drain select transistor, a plurality of memory cells, and a second source select transistor;
a third cell string coupled to the first bit line, the third cell string including a third drain select transistor, a plurality of memory cells, and a third source select transistor; and
a fourth cell string coupled to the first bit line, fourth cell string including a fourth drain select transistor, a plurality of memory cells, and a fourth source select transistor,
wherein a plurality of data bits are stored in a first memory cell group formed by a first memory cell coupled to a first word line among the plurality of memory cells included in the first cell string, and a third memory cell coupled to the first word line among the plurality of memory cells included in the third cell string, and
wherein a number of data bits stored in each of the first and third memory cells is a non-integer.

10. The semiconductor memory device according to claim 9,
wherein a plurality of data bits are stored in a second memory cell group formed by a second memory cell coupled to the first word line among the plurality of memory cells included in the second cell string, and a fourth memory cell coupled to the first word line among the plurality of memory cells included in the fourth cell string, and
wherein a number of data bits stored in each of the second and fourth memory cells is a non-integer.

11. The semiconductor memory device according to claim 10, wherein the first to fourth drain select transistors are controlled through different drain select lines.

12. The semiconductor memory device according to claim 10,
wherein the first source select transistor and the second source select transistor are controlled through an identical source select line, and
wherein the third source select transistor and the fourth source select transistor are controlled through an identical source select line.

13. A semiconductor memory device comprising:
a first cell string coupled to a first bit line, the first cell string including a first drain select transistor, a plurality of memory cells, and a first source select transistor;
a second cell string coupled to the first bit line, the second cell string including a second drain select transistor, a plurality of memory cells, and a second source select transistor; and
a third cell string coupled to the first bit line, the third cell string including a third drain select transistor, a plurality of memory cells, and a third source select transistor,
wherein a plurality of data bits are stored in a memory cell group formed by a first memory cell coupled to a first word line among the plurality of memory cells included in the first cell string, a second memory cell coupled to the first word line among the plurality of memory cells included in the second cell string, and a third memory cell coupled to the first word line among the plurality of memory cells included in the third cell string.

14. The semiconductor memory device according to claim 13, wherein:
the first to third drain select transistors are controlled through different drain select lines, and
the first to third source select transistors are controlled through an identical source select line.

15. The semiconductor memory device according to claim 13, wherein:
the first memory cell is programmed to one of three threshold voltage states,
the second memory cell and the third memory cell are each programmed to one of five threshold voltage states, and
the memory cell group stores six bits of data.

16. A semiconductor memory device including a plurality of cell strings coupled between a bit line and a source line, the plurality of cell strings each comprising:
a drain select transistor coupled to the bit line;
a source select transistor coupled to the source line; and
a plurality of memory cells coupled in series between the drain select transistor and the source select transistor, and coupled to respective word lines,
wherein a plurality of data bits are stored in a memory cell group formed by at least a part of the memory cells of the cell strings, the part being coupled to a first word line among the word lines.

17. The semiconductor memory device according to claim 16, wherein:
the memory cell group includes first and second memory cells among the memory cells of the cell strings,
a first cell string including the first memory cell and a second cell string including the second memory cell are disposed adjacent to each other, and
a first drain select transistor included in the first cell string and a second drain select transistor included in the second cell string are controlled through different drain select lines.

18. The semiconductor memory device according to claim 17, wherein a first source select transistor included in the first cell string and a second source select transistor included in the second cell string are controlled through an identical source select line.

19. The semiconductor memory device according to claim 16, wherein:
the memory cell group includes first and second memory cells among the memory cells of the cell strings,
a first cell string including the first memory cell and a second cell string including the second memory cell are odd-numbered cell strings among the plurality of cell strings, and
a first drain select transistor included in the first cell string and a second drain select transistor included in the second cell string are controlled through different drain select lines.

20. The semiconductor memory device according to claim 16, wherein:
the memory cell group includes first and second memory cells among the memory cells of the cell strings,
a first cell string including the first memory cell and a second cell string including the second memory cell are even-numbered cell strings among the plurality of cell strings, and
a first drain select transistor included in the first cell string and a second drain select transistor included in the second cell string are controlled through different drain select lines.

21. The semiconductor memory device according to claim 16, wherein:
the memory cell group includes first and second memory cells among the memory cells of the cell strings,
a first cell string including the first memory cell is disposed in a relatively outer portion among the plurality of cell strings and a second cell string including the second memory cell is disposed in a relatively central portion among the plurality of cell strings.

22. The semiconductor memory device according to claim 21, wherein the first memory cell and the second memory cell are each programmed to one of an identical number of threshold voltage states.

23. The semiconductor memory device according to claim 21, wherein the first memory cell and the second memory cell are each programmed to one of different numbers of threshold voltage states.

24. The semiconductor memory device according to claim 16, wherein:
the memory cell group includes first, second, and third memory cells among the memory cells of the cell strings,
a first cell string including the first memory cell and a second cell string including the second memory cell are disposed adjacent to each other, and the second cell string and a third cell string including the third memory cell are disposed adjacent to each other, and
a first drain select transistor included in the first cell string, a second drain select transistor included in the second cell string, and a third drain select transistor included in the third cell string are controlled through different drain select lines.

25. The semiconductor memory device according to claim 24, wherein:
the first memory cell is programmed to one of three threshold voltage states, and the second and third memory cells are each programmed to one of five threshold voltage states, and
the memory cell group stores six bits of data.
